(19) United States
(12) Patent Application Publication
(10) Pub. No.: US 2026/0190331 A1
(43) Pub. Date: Jul. 2, 2026

(54) APPARATUS INCLUDING GATE STRUCTURES COMPRISING MULTIPLE WORK FUNCTION MATERIALS AND RELATED ELECTRONIC DEVICES AND METHODS

(71) Applicant: Micron Technology, Inc., Boise, ID (US)

(72) Inventor: Toshiyasu Fujimoto, Hiroshima (JP)

(21) Appl. No.: 19/413,408

(22) Filed: Dec. 9, 2025

Related U.S. Application Data
(60) Provisional application No. 63/740,578, filed on Dec. 31, 2024.

(51) Int. Cl. H10B 12/00; H10D 64/27; H10D 64/66

(52) U.S. Cl. CPC H10B 12/488; H10B 12/053; H10B 12/315; H10B 12/34; H10B 12/482; H10D 64/513; H10D 64/666; H10D 64/667

(57) ABSTRACT

An apparatus comprises gate structures in a substrate, the gate structures comprising a metal material and a low work function material adjacent to the metal material. Cell capacitors are electrically coupled to source/drain regions of the substrate and bit lines are electrically coupled to other source/drain regions of the substrate. Contacts extend into the low work function material of the gate structures, the low work function material and materials surrounding the contacts do not comprise a polysilicon material. Additional apparatus and methods of forming the apparatus are disclosed.

### CROSS-REFERENCE TO RELATED APPLICATIONS

This application claims the benefit under 35 U.S.C. § 119(e) of U.S. Provisional Patent Application Ser. No. 63/740,578, filed Dec. 31, 2024, the disclosure of which is hereby incorporated herein in its entirety by this reference.

### TECHNICAL FIELD

This disclosure relates generally to the field of electronic device design and fabrication. More particularly, the disclosure relates to apparatus and electronic devices including gate structures having multiple work function materials and no polysilicon material, and to related methods of forming the apparatus.

### BACKGROUND

As the data storage capacity of electronic devices increases and the degree of integration increases, dimensions of a unit cell are reduced. That is, design rules of features (e.g., capacitors and transistors) present in each unit cell are reduced. Dynamic Random Access Memory (DRAM) devices are widely used in consumer electronic products. In order to increase the integration of components in a DRAM device and improve its overall electrical performance, methods of manufacturing the DRAM device continue to reduce dimensions of the features. However, as feature sizes continue to shrink, other challenges arise. For example, gate induced drain leakage (GIDL) is a significant performance issue that arises with decreasing dimensions of the unit cell.

GIDL current occurs due to electrons from a valence band tunneling to a conduction band as a result of excessive band bending in a gate/drain overlap region of the unit cell. As design rules decrease to less than 100 nm, various solutions to GIDL have been proposed. For instance, a thickness of a gate oxide material has been reduced to provide for suitable gate control over a sub-threshold region. In addition, doping concentration in a channel and source/drain regions have been increased to improve punch-through characteristics. However, some of the proposed solutions have resulted in additional performance issues or even more GIDL current.

### BRIEF DESCRIPTION OF THE DRAWINGS

For a detailed understanding of the disclosure, reference should be made to the following detailed description, taken in conjunction with the accompanying drawings, in which like elements have generally been designated with like numerals, and wherein:

FIG. 1 is a perspective view of a portion of an apparatus including word lines and bit lines according to embodiments of the disclosure;

FIG. 2 is a simplified, partial top-down view of a portion of an apparatus including word lines and bit lines according to embodiments of the disclosure;

FIG. 3 is a cross-sectional view of an apparatus including word lines and bit lines according to embodiments of the disclosure;

FIGS. 4A, 5A, 6A, 7A, 8A, and 9A are simplified, partial top-down views of a method of forming an apparatus at various fabrication stages according to embodiments of the disclosure;

FIGS. 4B, 5B, 6B, 7B, 8B, and 9B are simplified, partial cross-sectional views along the B-B line of FIG. 4A of a method of forming an apparatus at various fabrication according to embodiments of the disclosure;

FIGS. 4C, 5C, 6C, 7C, 8C, and 9C are simplified, partial cross-sectional views along the C-C line of FIG. 4A of a method of forming an apparatus at various fabrication according to embodiments of the disclosure;

FIG. 10 is a functional block diagram of an electronic device in accordance with embodiments of the disclosure; and

FIG. 11 is a schematic block diagram of an electronic system in accordance with embodiments of the disclosure.

### DETAILED DESCRIPTION

Gate structures of an apparatus are disclosed that include word lines having dual work function materials and bit lines electrically coupled to the word lines. One of the work function materials is a low work function material and another of the work function materials is a metal material. The materials of the gate structures do not include (e.g., lack) a polysilicon material. Contacts (e.g., word line contacts) to the gate structures are electrically coupled to the low work function material of the word lines, with the low work function material surrounding a lower region of the contact. Unlike with conventional gate structures, the contacts are not in contact with (e.g., lack contact with) a polysilicon material. By not including a polysilicon material surrounding or proximal to the contacts, gate induced drain leakage (GIDL) in the apparatus is reduced. At the same time, other electrical properties of the apparatus are not affected, such as refresh rate and resistivity.

The illustrations presented herein are not actual views of any apparatus, or any component thereof, but are merely idealized representations, which are employed to describe embodiments of the invention.

As used herein, the singular forms following “a,” “an,” and “the” are intended to include the plural forms as well, unless the context clearly indicates otherwise.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, any relational term, such as “first,” “second,” “top,” “bottom,” “upper,” “lower,” “above,” “beneath,” “side,” “upward,” “downward,” etc., is used for clarity and convenience in understanding the disclosure and accompanying drawings, and does not connote or depend on any specific preference or order, except where the context clearly indicates otherwise. For example, these terms may refer to an orientation of elements of any apparatus when utilized in a conventional manner. Furthermore, these terms may refer to an orientation of elements of any apparatus as illustrated in the drawings.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “about” used in reference to a given parameter is inclusive of the stated value and has the meaning dictated by the context (e.g., it includes the degree of error associated with measurement of the given parameter, as well as variations resulting from manufacturing tolerances, etc.). For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

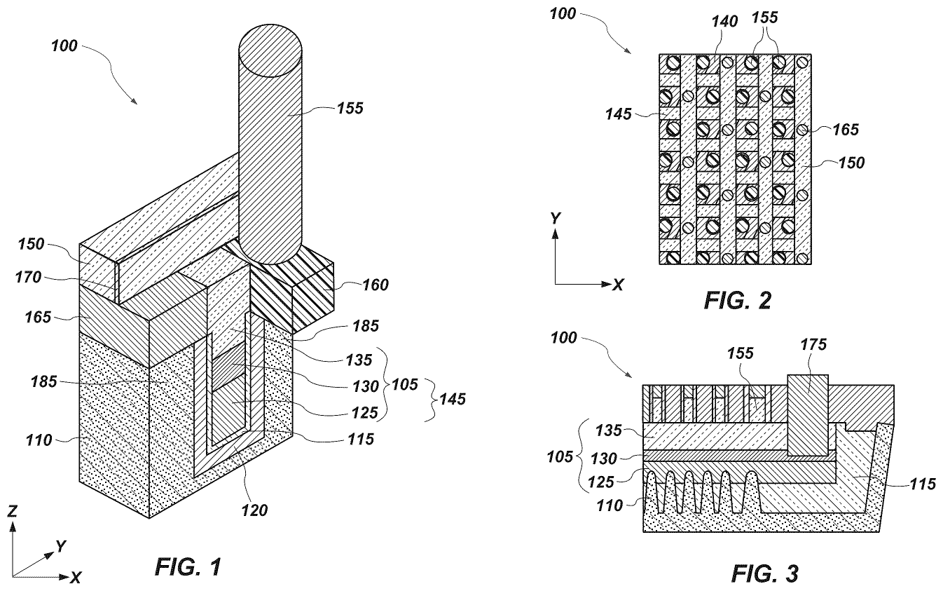

FIGS. 1-3 illustrate an apparatus 100 according to embodiments of the disclosure. The apparatus 100 includes gate structures 105 in a substrate 110 (e.g., silicon 110). The gate structures 105 are separated from the substrate 110 by one or more dielectric materials, such as an oxide material 115 (e.g., a shallow trench isolation (STI) oxide), which surrounds the gate structures 105. A channel region 120 may also surround the gate structures 105, separating the gate structures 105 and the oxide material 115 from the substrate 110. The gate structures 105 include a metal material 125, a low work function material 130 adjacent to the metal material 125, and a cap material 135 adjacent to the low work function material 130. The gate structures 105 may be considered so-called “hybrid” gate structures in that multiple materials constitute the gate structures 105. The materials of the gate structures 105, however, exclude a polysilicon material. The gate structures 105 may be configured as recessed access devices (RADs), which function as transistors (e.g., access transistors) in the apparatus 100.

The oxide material 115 divides the substrate 110 into active regions 140 (e.g., active silicon), as shown in FIG. 2. Word lines 145 including the metal material 125 and the low work function material 130 extend across the active regions 140 in the X direction, and bit lines 150 extend across the active regions 140 in the Y direction. The metal material 125 and the low work function material 130 function as the word lines 145 of the gate structures 105. Each active region 140 is divided into source/drain regions 185 by the word lines 145. The source/drain regions 185 are on both sides, in the Y direction, of each gate structure 105 in the active regions 140, as shown in FIG. 1. The word lines 145 are electrically coupled to cell capacitors 155 by cell contacts 160, and the bit lines 150 are electrically coupled to (e.g., electrically connected to) the source/drain regions 185 by bit contacts 165. A spacer material 170 separates the bit lines 150 and the cell capacitors 155. One of the source/drain regions 185 is electrically coupled to a corresponding bit line 150 through the bit contact 165. The other of the source/drain regions 185 is electrically coupled to a corresponding cell capacitor 155 through the cell contact 160. The cell capacitors 155 are, therefore, electrically coupled to a source/drain region 185 of the substrate 110, and the bit lines 150 are electrically coupled to another source/drain region 185 of the substrate 110. The channel region 120 is produced around the gate structures 105 when a predetermined “on” potential is applied to the word lines 145, so that the source/drain regions 185 are electrically coupled to each other.

The metal material 125 of the word lines 145 may be an electrically conductive material that exhibits a work function of from about 4.5 to about 4.7. The metal material 125 may include, but is not limited to, titanium, titanium nitride, tantalum, tantalum nitride, tungsten, tungsten nitride, or a combination thereof. In some embodiments, the metal material 125 is titanium nitride. The relatively high work function of the metal material 125 may be selected to provide a low resistance value to the word lines 145 and to reduce off leakage of the transistors.

The low work function material 130 of the word lines 145 may exhibit a low resistance, such as being a metal material or a chemical compound of a metal. The low work function material 130 exhibits a different work function than the work function of the metal material 125 and also exhibits a work function similar to that of polysilicon. The metal of the low work function material 130 may have a work function of from about 3.8 to about 4.2, lower than the work function of the metal material 125. The low work function material 130 may have a resistivity of from about 15 uΩ cm to about 45 uΩ cm. By way of example only, the low work function material 130 may be hafnium (Hf), zirconium (Zr), tantalum (Ta), silver (Ag), aluminum (Al), copper (Cu), a combination thereof, a chemical compound of Hf, Zr, Ta, Ag, Al, or Cu, or a combination thereof. The chemical compound may be a nitride or a silicide of the metal of the low work function material 130. However, other metals or metal compounds having a work function from about 3.8 to about 4.2 may be used. In some embodiments, the low work function material 130 is hafnium, zirconium, or tantalum. The low work function material 130 is vertically adjacent to the metal material 125 of the gate structures 105.

The cap material 135 may be formed of and include a dielectric material, such as a silicon oxide material or a silicon nitride material. The cap material 135 is vertically adjacent to the low work function material 130 of the gate structure 105. In some embodiments, the cap material 135 is silicon nitride.

In some embodiments, the gate structures 105 include titanium nitride as the metal material 125, hafnium, zirconium, or tantalum as the low work function material 130, and silicon nitride as the cap material 135.

Relative thicknesses of the metal material 125 and the low work function material 130 in the word lines 145 depend on desired electrical performance properties of the apparatus 100, such as electrical performance properties of the transistors of the apparatus 100. The thickness of the metal material 125 may range from about 10 nm to about 50 nm and the thickness of the low work function material 130 may range from about 10 nm to about 30 nm. The materials of the metal material 125 and the low work function material 130 may be selected to provide a low resistance value to the word lines 145 and reduce an off-leakage current of the transistors of the apparatus 100, when the transistors are in an “off” state. The metal material 125 and the low work function material 130 may also achieve the reduced GIDL while simultaneously achieving low resistance for the word lines 145.

The gate structures 105 lack a polysilicon material (e.g., do not include a polysilicon material) and, therefore, also lack direct contact between such a polysilicon material and other components of the apparatus 100. In other words, materials surrounding (e.g., directly surrounding) or proximal to (e.g., directly proximal to) the gate structures 105 in the apparatus 100 lack a polysilicon material (e.g., exclude a polysilicon material).

As shown in FIG. 3, the apparatus 100 may include the gate structures 105 of the transistors in combination with charge-storage devices (e.g., cell capacitors 155). In comparison to FIG. 1, the apparatus 100 in FIG. 3 illustrates multiple gate structures 105 and the cell capacitors 155 overlying a corresponding gate structure 105. The apparatus 100 may, for example, be used in dynamic random access memory (DRAM). The DRAM may include an array of memory cells, with the word lines 145 extending across the gate structures 105 of the transistors of the memory cells in order to access rows of the DRAM array. The transistors and cell capacitors 155 form the memory cells of the DRAM array. The bit lines 150 may extend along columns of the DRAM array, and each memory cell of the DRAM array may be uniquely addressed by a word line/bit line combination. One of the transistors in a DRAM cell of the DRAM array may be electrically coupled to one of the source/drain regions 185 by the cell capacitor 155, and the other of the source/drain regions 185 may be electrically coupled with the bit line 150. In addition to being utilized in memory cells of DRAM arrays, the transistors may have numerous other uses in integrated circuits, and may have many applications throughout memory, logic, etc.

Contacts 175 (e.g., word line contacts) are adjacent to the gate structures 105 and the cell capacitors 155 and electrically couple the low work function material 130 to overlying features (not shown) of the apparatus 100. The contacts 175 may be formed of and include an electrically conductive material. The contacts 175 are laterally adjacent to the gate structures 105 and the cell capacitors 155. As shown most clearly in the perspective of FIG. 3, the contacts 175 and the low work function material 130 of the gate structures 105 are in direct contact with one another, with the contacts 175 extending into the low work function material 130. A portion of the low work function material 130 surrounds the contact 175, with the low work function material 130 directly contacting sidewalls and a lower surface of the contact 175. The low work function material 130 surrounds a lower region of the contact 175, and the cap material 135 surrounds a middle region of the contact 175. However, none of the materials of the gate structures 105 that directly contact the contact 175 is a polysilicon material.

The gate structures 105 in the apparatus 100 according to embodiments of the disclosure include the low work function material 130 formed from a metal or a metal compound, in comparison to gate structures of conventional apparatus, which may include a polysilicon material in a corresponding location (e.g., adjacent to a metal material). The highly resistive polysilicon material in the conventional apparatus may result in electrical contact between the metal material, the polysilicon material, and a corresponding contact, which results in so-called “open” word lines of the conventional apparatus and reduced electrical performance properties. The polysilicon material around the corresponding contact may also undesirably cause the word lines of the conventional apparatus to exhibit high resistance, which causes delays in transistor switching. In contrast, in the apparatus 100 according to embodiments of the disclosure, no polysilicon material is proximal to the contact 175 since the metal material 125, the low work function material 130, and the cap material 135 are not formed of polysilicon. In addition, no polysilicon material is surrounding or proximal to the contact 175 of the apparatus 100. The materials that are present proximal to the lower region and the middle region of the contact 175 do not include a polysilicon material. As shown most clearly in FIGS. 1 and 3, the gate structures 105 of the apparatus 100 include the metal material 125 in direct contact with the low work function material 130, the low work function material 130 in direct contact with the cap material 135, and the lower and middle regions of the contact 175 in direct contact with the low work function material 130 and the cap material 135.

Since no polysilicon material is in direct contact with or proximal to the contact 175 and since the low work function material 130 and the metal material 125 exhibit different work functions, GIDL is decreased in the apparatus 100 when the word lines 145 (e.g., the recessed access devices) are in the “off” state. The low work function material 130 in the gate structures 105 also provides improved electrical performance characteristics to the apparatus 100 at the same time as suppressing GIDL. By way of example only, the apparatus 100 exhibits improved refresh characteristics, since refresh rate depends on the amount of GIDL in the transistors, while also reducing the electrical resistance of the word lines 145. The gate structures 105 may also contribute to a high drive current for the apparatus 100. Therefore, the apparatus 100 according to embodiments of the disclosure achieves an appropriate balance between GIDL and other electrical performance properties.

Accordingly, in some embodiments, an apparatus comprises gate structures in a substrate, the gate structures comprising a metal material and a low work function material adjacent to the metal material. Cell capacitors are electrically coupled to a source/drain region of the substrate and bit lines are electrically coupled to another source/drain region of the substrate. Contacts extend into the low work function material of the gate structures, the low work function material and materials surrounding the contacts do not comprise a polysilicon material.

Accordingly, in other embodiments, an apparatus comprises gate structures in a substrate, materials of the gate structures comprising a metal material and a low work function material and excluding a polysilicon material. Cell capacitors are electrically coupled to source/drain regions of the substrate and bit lines are electrically coupled to another of the source/drain regions of the substrate. Contacts extend into the low work function material of the gate structures, the low work function material surrounding a lower region of the contacts.

While embodiments of the disclosure describe and illustrate the gate structures 105 as being a component (e.g., an access device) of a planar DRAM device, the gate structures 105 may be used as a component of other DRAM devices including, but not limited to, a 3D DRAM device.

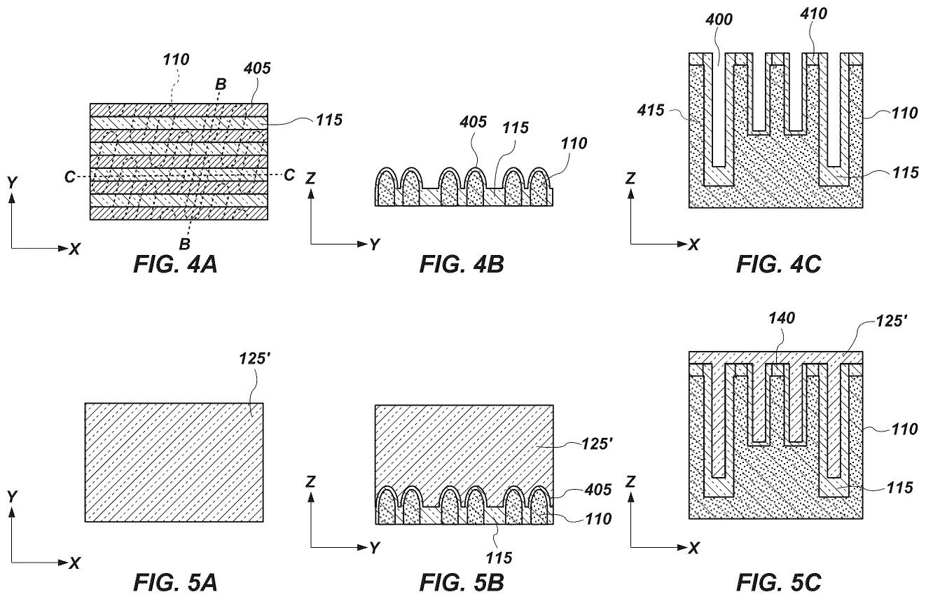

A method of forming the apparatus 100 that includes the gate structures 105 is disclosed. The method of forming the apparatus 100 according to embodiments of the disclosure may reduce the number of process acts, such as by eliminating a photolithography act, compared to methods of forming conventional apparatus. The gate structures 105 include the metal material 125, the low work function material 130, and the cap material 135. As shown in FIGS. 4A-4C, trenches 400 are formed in the substrate 110, with the word lines 145 ultimately to be formed in the trenches 400. The trenches 400 may be formed by conventional techniques, such as by removing portions of the substrate 110 by a dry etch process. Dimensions of the trenches 400 may depend on desired dimensions of the gate structures 105 to be formed in the apparatus 100. The trenches 400 extend into the substrate 110 and are defined by sidewalls of the substrate 110. Some of the trenches 400 are positioned in the active regions 140, and other of the trenches 400 are positioned in an STI region 415. The trenches 400 in the STI region 415 may be relatively deeper than the trenches 400 in the active regions 140. The trenches 400 are formed using a patterned hardmask material 410. A gate oxide material 405 is formed in the trenches 400 and on the substrate 110, as shown in the perspective of FIG. 4B. The gate oxide material 405 may be located over upper portions of the substrate 110 that protrude above the oxide material.

The oxide material 115 may be formed in the trenches 400 and on the sidewalls of the substrate 110, as shown in the perspective of FIG. 4C. The oxide material 115 may be conformally formed in the trenches 400, such as by a CVD or PVD process. The oxide material 115 may partially fill the trenches 400, with a portion of the trenches 400 remaining unfilled. The oxide material 115 may function as an STI oxide of the transistors of the apparatus 100. The gate oxide material 405 may be located over upper portions of the substrate 110 that protrude above the oxide material, as shown in FIG. 4B. The hardmask material 410 is present over upper portions of the substrate 110, as shown in FIG. 4C. The hardmask material 410 may be an oxide material, such as a silicon oxide material.

As shown in FIGS. 5A-5C, a metal material 125′ (e.g., a word line metal) of the metal material 125 may be formed within the trenches 400 and over the oxide material 115 and the substrate 110. The metal material 125′ may fill the remaining volume of the trenches 400 and extend over the hardmask material 410. The metal material 125′, therefore, extends from a bottom of the trenches 400 to above the substrate 110 and the hardmask material 410. The metal material 125′ of the word lines 145 may be formed by CVD, PVD, or other deposition technique.

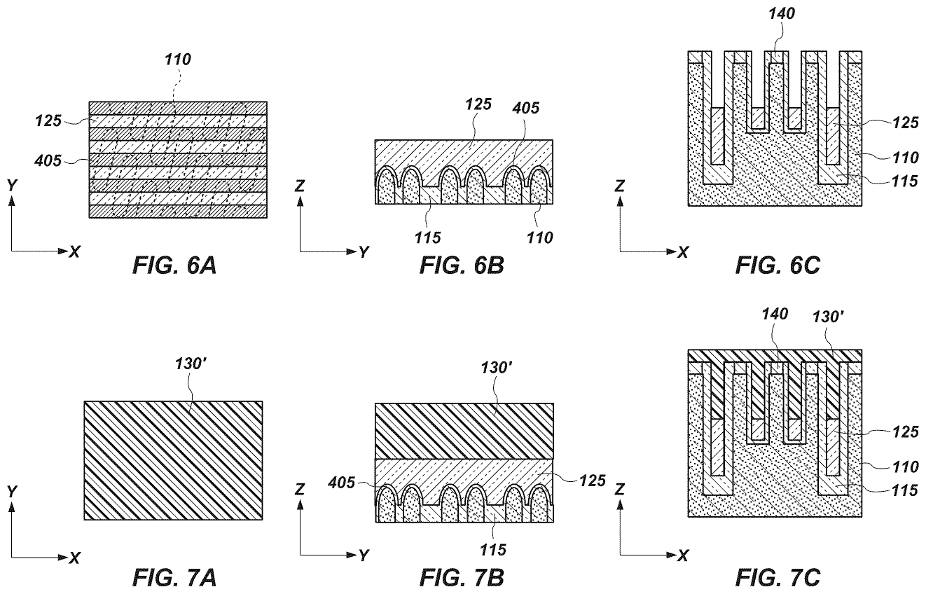

A portion of the metal material 125′ may be removed to form the metal material 125 of the word lines 145 in the trenches 400 and over the oxide material 115 and the substrate 110, as shown in FIGS. 6A-6C. The metal material 125 may remain in lower regions of the trenches 400 such that the metal material 125 is recessed, as shown in FIG. 6C. Upper surfaces of the recessed metal material 125 may be substantially coplanar with one another. The portion of the metal material 125′ may be removed, for example, by a dry etch process.

As shown in FIGS. 7A-7C, a low work function metal 130′ is formed over the metal material 125 and the hardmask material 410, filling the trenches 400. The low work function metal 130′ may be formed by CVD, PVD, or other deposition technique. The low work function metal 130′ directly contacts the metal material 125 in the trenches 400.

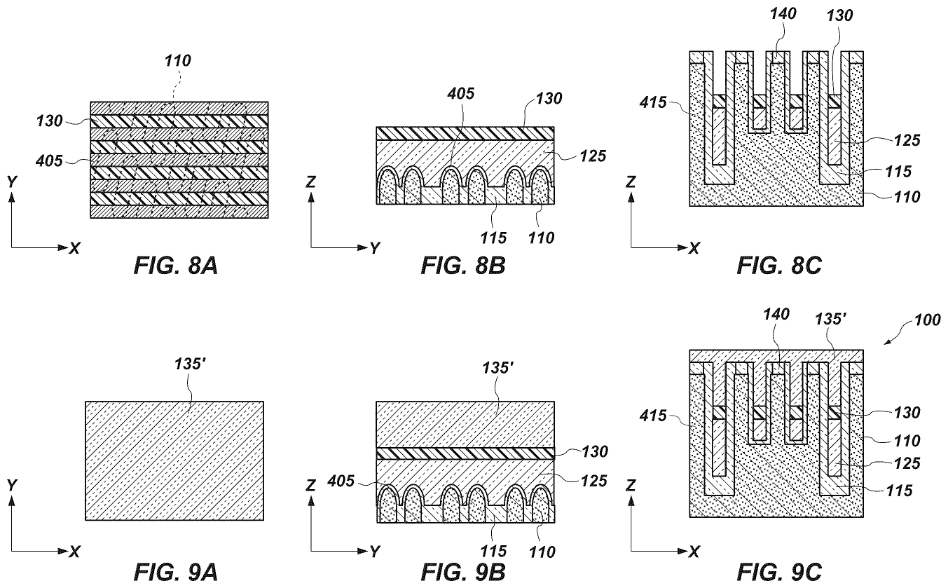

A portion of the low work function metal 130′ may be removed, recessing the low work function metal 130′ in the trenches 400 as shown in FIGS. 8A-8C. Upper surfaces of the recessed low work function metal 130′ remaining in the trenches 400 may be substantially coplanar with one another. The portion of the low work function metal 130′ may be removed, for example, by a dry etch process. The low work function metal 130′ may be located in middle regions of the trenches 400, as shown in FIG. 8C.

A cap material 135′ may be formed over the low work function metal 130′, the hardmask material 410, and the oxide material 115, as shown in FIGS. 9A-9C. The cap material 135′ may be formed by conventional techniques. The cap material 135′ may substantially completely fill the trenches 400. A portion of the cap material 135′ may subsequently be removed from over the hardmask material 410 and the oxide material 115, producing the cap material 135 of the gate structures 105 in the trenches 400. The cap material 135 is directly vertically adjacent to the low work function metal 130′, which is directly vertically adjacent to the metal material 125, with the metal material 125, the low work function material 130, and the cap material 135 constituting the gate structures 105. The hardmask material 410 may subsequently be removed before forming other components of the apparatus 100. Additional process acts are conducted to form the other components of the apparatus 100 of FIGS. 1-3, such as forming the bit contacts 165, the bit lines 150, the cell contacts 160, the spacer material 170, and the cell capacitors 155. The additional process acts are conducted by conventional techniques.

Accordingly, a method of forming an apparatus comprises forming trenches in a substrate, forming a metal material in the trenches, and removing a portion of the metal material to recess the metal material in the trenches. A low work function material is formed in the trenches vertically adjacent to the metal material and a portion of the low work function material is removed to recess the low work function material in the trenches. A cap material is formed in the trenches vertically adjacent to the low work function material. The cap material, the low work function material, and the metal material comprise gate structures. Bit lines are formed adjacent to the gate structures and cell capacitors are formed adjacent to the bit lines. Contacts are formed laterally adjacent to the cell capacitors and extending into the low work function material of the gate structures.

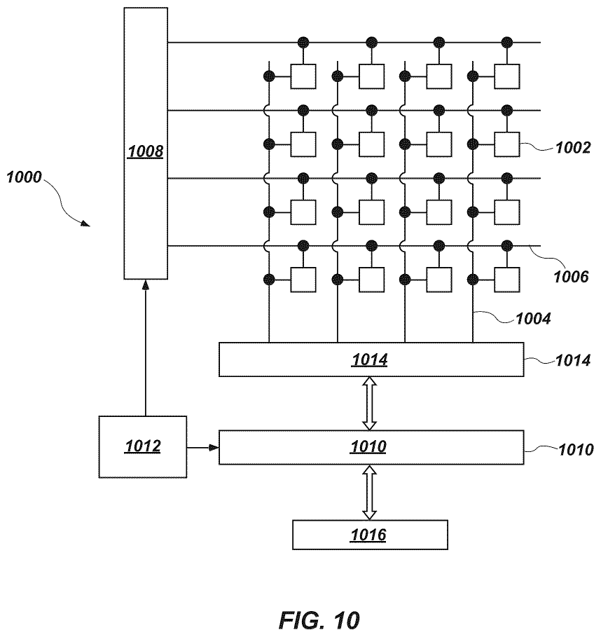

Additional processing acts may subsequently be conducted to form an electronic device that includes one or more apparatus 100. The apparatus 100 is subjected to additional processing acts to form an electronic device 1000 (e.g., a memory device) including the one or more apparatus 100. Such additional processing may employ conventional processes and conventional processing equipment. The electronic device 1000 may include, for example, embodiments of the apparatus 100 previously described. As shown in FIG. 10, the electronic device 1000 may include memory cells 1002, digit lines 1004 (e.g., the bit lines 150), word lines 1006 (e.g., the word lines 145), a row decoder 1008, a column decoder 1010, a memory controller 1012, a sense device 1014, and an input/output device 1016.

The memory cells 1002 of the electronic device 1000 are programmable to at least two different logic states (e.g., logic 0 and logic 1). Each memory cell 1002 may individually include a storage device (e.g., the cell capacitor 155), an access device (e.g., the transistor), and the apparatus 100 according to embodiments of the disclosure. The capacitor stores a charge representative of the programmable logic state (e.g., a charged capacitor may represent a first logic state, such as a logic 1; and an uncharged capacitor may represent a second logic state, such as a logic 0) of the memory cell 1002. The transistor grants access to the cell capacitor 155 upon application (e.g., by way of one of the word lines 145) of a minimum threshold voltage to a semiconductive channel thereof for operations (e.g., reading, writing, rewriting) on the capacitor.

The digit lines 1004 are electrically coupled to the capacitors of the memory cells 1002 by way of the transistors of the memory cells 1002. The word lines 1006 extend perpendicular to the digit lines 1004 and are electrically coupled to gate structures 105 of the transistors of the memory cells 1002. Operations may be performed on the memory cells 1002 by activating appropriate digit lines 1004 and word lines 1006. Activating a digit line 1004 or a word line 1006 may include applying a voltage potential to the digit line 1004 or the word line 1006. Each column of memory cells 1002 may individually be electrically coupled to one of the digit lines 1004, and each row of the memory cells 1002 may individually be electrically coupled to one of the word lines 1006. Individual memory cells 1002 may be addressed and accessed through the intersections (e.g., cross points) of the digit lines 1004 and the word lines 1006.

The memory controller 1012 may control the operations of the memory cells 1002 through various components, including the row decoder 1008, the column decoder 1010, and the sense device 1014. The memory controller 1012 may generate row address signals that are directed to the row decoder 1008 to activate (e.g., apply a voltage potential to) predetermined word lines 1006, and may generate column address signals that are directed to the column decoder 1010 to activate (e.g., apply a voltage potential to) predetermined digit lines 1004. The memory controller 1012 may also generate and control various voltage potentials employed during the operation of the electronic device 1000. In general, the amplitude, shape, and/or duration of an applied voltage may be adjusted (e.g., varied), and may be different for various operations of the electronic device 1000.

During use and operation of the electronic device 1000, after being accessed, a memory cell 1002 may be read (e.g., sensed) by the sense device 1014. The sense device 1014 may compare a signal (e.g., a voltage) of an appropriate digit line 1004 to a reference signal in order to determine the logic state of the memory cell 1002. If, for example, the digit line 1004 has a higher voltage than the reference voltage, the sense device 1014 may determine that the stored logic state of the memory cell 1002 is a logic 1, and vice versa. The sense device 1014 may include transistors and amplifiers to detect and amplify a difference in the signals. The detected logic state of a memory cell 1002 may be output through the column decoder 1010 to the input/output device 1016. In addition, a memory cell 1002 may be set (e.g., written) by similarly activating an appropriate word line 1006 and an appropriate digit line 1004 of the electronic device 1000. By controlling the digit line 1004 while the word line 1006 is activated, the memory cell 1002 may be set (e.g., a logic value may be stored in the memory cell 1002). The column decoder 1010 may accept data from the input/output device 1016 to be written to the memory cells 1002. Furthermore, a memory cell 1002 may also be refreshed (e.g., recharged) by reading the memory cell 1002. The read operation will place the contents of the memory cell 1002 on the appropriate digit line 1004, which is then pulled up to full level (e.g., full charge or discharge) by the sense device 1014. When the word line 1006 associated with the memory cell 1002 is deactivated, all of memory cells 1002 in the row associated with the word line 1006 are restored to full charge or discharge.

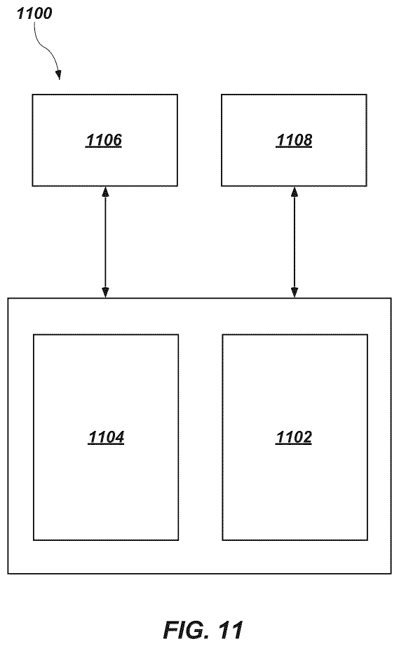

The apparatus 100 according to embodiments of the disclosure may be used in embodiments of electronic systems of the disclosure. For example, FIG. 11 is a block diagram of an illustrative electronic system 1100 according to embodiments of disclosure. The electronic system 1100 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 1100 includes at least one electronic device 1000. The electronic device 1000 may include, for example, one or more apparatus 100 as previously described herein. The electronic system 1100 may further include at least one electronic signal processor device 1104 (often referred to as a “microprocessor”). The electronic signal processor device 1104 may, optionally, include one or more apparatus 100 as previously described herein. The electronic system 1100 may further include one or more input devices 1106 for inputting information into the electronic system 1100 by a user, such as, for example, a mouse or other pointing device, a keyboard, a touchpad, a button, or a control panel. The electronic system 1100 may further include one or more output devices 1108 for outputting information (e.g., visual or audio output) to a user such as, for example, a monitor, a display, a printer, an audio output jack, a speaker, etc. In some embodiments, the input device 1106 and the output device 1108 may comprise a single touchscreen device that can be used both to input information to the electronic system 1100 and to output visual information to a user. The input device 1106 and the output device 1108 may communicate electrically with one or more of the electronic device 1102 and the electronic signal processor device 1104.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. An apparatus comprising:
gate structures in a substrate, the gate structures comprising a metal material and a low work function material adjacent to the metal material;
cell capacitors electrically coupled to a source/drain region of the substrate;
bit lines electrically coupled to another source/drain region of the substrate; and
contacts extending into the low work function material of the gate structures, wherein materials surrounding the contacts do not comprise a polysilicon material.

2. The apparatus of claim 1, wherein the metal material comprises titanium nitride and the low work function material comprises hafnium, zirconium, tantalum, or a chemical compound thereof.

3. The apparatus of claim 1, wherein the low work function material surrounds a lower region of the contacts.

4. The apparatus of claim 1, wherein the low work function material directly contacts a lower surface and sidewalls of the contacts.

5. The apparatus of claim 1, wherein the gate structures exclude a polysilicon material.

6. The apparatus of claim 1, wherein the materials surrounding the contacts exclude a polysilicon material.

7. The apparatus of claim 6, wherein the materials surrounding the contacts comprise materials in direct contact with the contacts.

8. The apparatus of claim 1, wherein the metal material and the low work function material comprise word lines electrically coupled to the cell capacitors.

9. The apparatus of claim 1, wherein the contacts are configured as word line contacts.

10. An apparatus comprising:
gate structures in a substrate, materials of the gate structures comprising a metal material and a low work function material and excluding a polysilicon material;
cell capacitors electrically coupled to source/drain regions of the substrate;
bit lines electrically coupled to another of the source/drain regions of the substrate; and
contacts extending into the low work function material of the gate structures, the low work function material surrounding a lower region of the contacts.

11. The apparatus of claim 10, wherein the gate structures are recessed in the substrate.

12. The apparatus of claim 10, wherein the contacts are electrically coupled to the cell capacitors and the gate structures.

13. The apparatus of claim 10, wherein the contacts do not directly contact a polysilicon material.

14. The apparatus of claim 10, wherein the gate structures consist of the metal material, the low work function material, and a cap material.

15. The apparatus of claim 14, wherein the contacts directly contact the low work function material.

16. A method of forming an apparatus, comprising:
forming trenches in a substrate;
forming a metal material in the trenches;
removing a portion of the metal material to recess the metal material in the trenches;
forming a low work function material in the trenches vertically adjacent to the metal material;
removing a portion of the low work function material to recess the low work function material in the trenches;
forming a cap material in the trenches vertically adjacent to the low work function material, the cap material, the low work function material, and the metal material comprising gate structures;
forming bit lines adjacent to the gate structures;
forming cell capacitors adjacent to the bit lines; and
forming contacts laterally adjacent to the cell capacitors and extending into the low work function material of the gate structures.

17. The method of claim 16, wherein forming a low work function material in the trenches vertically adjacent to the metal material comprises forming hafnium, zirconium, tantalum, or a chemical compound thereof vertically adjacent to the metal material.

18. The method of claim 16, wherein forming contacts laterally adjacent to the cell capacitors and extending into the low work function material comprises surrounding a lower portion of the contacts with the low work function material, the low work function material excluding a polysilicon material.

19. The method of claim 18, wherein forming contacts laterally adjacent to the cell capacitors and extending into the low work function material comprises forming the contacts in direct contact with the low work function material.

20. The method of claim 16, wherein forming contacts laterally adjacent to the cell capacitors and extending into the low work function material of the gate structures comprises surrounding a lower portion of the contacts with the low work function material and the cap material.
